(19) United States
(12) Patent Application Publication
(10) Pub. No.: US 2012/0155044 A1
(43) Pub. Date: Jun. 21, 2012

(54) ELECTRONIC CIRCUIT BOARD AND A RELATED METHOD THEREOF

(75) Inventors: David Mulford Shaddock, Troy, NY (US); Vinayak Tilak, Niskayuna, NY (US); Tan Zhang, Niskayuna, NY (US)

(73) Assignee: GENERAL ELECTRIC COMPANY, SCHENECTADY, NY (US)

(21) Appl. No.: 12/971,862

(22) Filed: Dec. 17, 2010

(51) Int. Cl. H05K 7/00; H05K 3/10

(52) U.S. Cl. 361/783; 29/846

(57) ABSTRACT

An apparatus includes a set of first metal contact pads disposed on a low temperature co-fired ceramic substrate. A plurality of metalized interconnectors extend between a digital electronic component and the low temperature co-fired ceramic substrate. The apparatus is configured to operate at a temperature greater than 250 degrees Celsius.

### STATEMENT REGARDING FEDERALLY SPONSORED RESEARCH & DEVELOPMENT

This invention was made with Government support under contract number DE-EE0002755 awarded by U.S. Dept. of Energy. The Government has certain rights in the invention.

### BACKGROUND

Embodiments presented herein relate generally to electronic circuit boards, and more specifically to a digital electronic circuit board and a related method thereof.

A printed circuit board (referred to as “PCB”) is often used to mechanically support and electrically connect electronic components using conductive pathways, tracks or signal traces that may be etched from metal sheets laminated onto a non-conductive substrate. A PCB populated with electronic components is a printed circuit assembly and may also be referred to as a printed circuit board assembly (PCBA).

Conventional conducting layers of the PCB are typically made of thin copper foil. Insulating layers dielectric is typically laminated together with epoxy resin prepreg. The vast majority of printed circuit boards are made by bonding a layer of copper over the entire substrate, sometimes on both sides, then removing unwanted copper after applying a temporary mask (e.g. by etching), leaving only the desired copper traces. Some PCBs are made by adding traces to the bare substrate usually by multiple electroplating steps.

After the PCB is completed, electronic components are attached to form a functional printed circuit assembly. In a through-hole technique, component leads are inserted in holes. In a surface-mount technique, the components are placed on pads on the outer surfaces of the PCB. In both kinds of techniques, component leads may be electrically and mechanically fixed to the board with a molten metal solder. The conventional PCB device may be limited to applications at a temperature below 200 degrees Celsius. Moreover the conventional PCB device may be susceptible to failure due to vibrations and corrosion.

There is a need for an improved electronic circuit device.

### BRIEF DESCRIPTION

In accordance with an exemplary embodiment of the present invention, an apparatus includes a set of first metal contact pads disposed on a low temperature co-fired ceramic substrate. A plurality of metalized interconnectors extend between a digital electronic component and the low temperature co-fired ceramic substrate. The apparatus is configured to operate at a temperature greater than 250 degrees Celsius.

In accordance with an exemplary embodiment of the present invention, a method includes providing an apparatus having a set of first metal contact pads disposed on a low temperature co-fired ceramic substrate, and a plurality of metalized interconnectors extending between a digital electronic component and the low temperature co-fired ceramic substrate. The method also includes utilizing the apparatus at a temperature greater than 250 degrees Celsius.

### DRAWINGS

These and other features, aspects, and advantages will become better understood when the following detailed description is read with reference to the accompanying drawings in which like characters represent like parts throughout the drawings, wherein:

FIG. 1 is a diagrammatical representation of an apparatus, for example an electronic circuit board for a high temperature device in accordance with an embodiment;

FIG. 2 is a diagrammatical representation of an apparatus, for example an electronic circuit board having a plurality of LTCC substrates in accordance with an embodiment;

FIG. 3 a diagrammatical representation of a plurality of metal bumps bonded to the LTCC substrate in accordance with an embodiment; and

FIG. 4 is a diagrammatical representation of a digital electronic component flip chip bonded to a LTCC substrate in accordance with an embodiment.

### DETAILED DESCRIPTION

According to embodiments presented herein, an apparatus, for example, an electronic circuit board and a related method thereof is disclosed. The electronic circuit board can include a low temperature co-fired ceramic substrate. A set of first metal contact pads can be disposed on the low temperature co-fired ceramic substrate. The electronic circuit board can further include a plurality of metalized interconnectors extending from a digital electronic component to the low temperature co-fired ceramic substrate. An electronic circuit board configured as described herein may be capable of operating at a temperature greater than 250 degrees Celsius, may demonstrate enhanced resistance to failure due to extreme conditions such as high temperature, vibration, and corrosion, and may provide low losses, for example, low inductance, and low resistance.

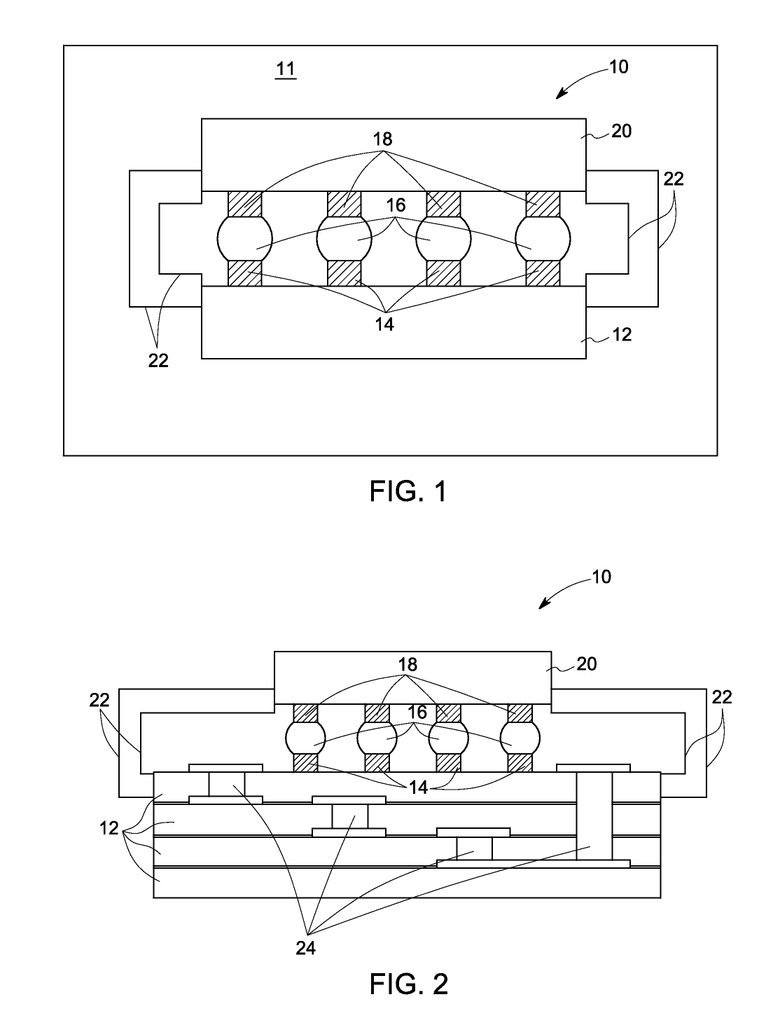

Referring to FIG. 1, therein is illustrated, an apparatus, for example specifically referred to as an electronic circuit board 10 for a high temperature device 11 in accordance with an embodiment. The illustrated electronic circuit board 10 can include a low temperature co-fired ceramic substrate (LTCC substrate) 12, and a set of first metal contact pads 14 disposed on the low temperature co-fired ceramic substrate 12. The set of first metal contact pads 14 includes at least one of gold, platinum, aluminum, nickel, or copper contact pads. The electronic circuit 10 may also include a plurality of metal bumps 16, each metal bump among the plurality of metal bumps 16 may be coupled to a corresponding first metal contact pad among the set of first metal contact pads 14. The plurality of metal bumps 16 includes at least one of gold, platinum, aluminum, nickel, or copper bumps. In some embodiments, the plurality of metal bumps 16 may include metal stud bumps. The electronic circuit board 10 may further include a set of second metal contact pads 18 disposed on the digital electronic component 20. Each metal bump among the plurality of metal bumps 16 may be coupled to a corresponding second metal contact pad among the set of second metal contact pads 18. The set of second metal contact pads 18 includes at least one of gold, platinum, aluminum, nickel, or copper contact pads.

In one embodiment, the plurality of metal bumps 16 may be bonded to the set of first metal contact pads 14 and the set of second metal contact pads 18 via a diffusion bonding. Diffusion bonding involves holding pre-machined components under load at an elevated temperature, possibly in a protective atmosphere or vacuum. In another embodiment, the plurality of metal bumps 16 may be bonded to the set of first metal contact pads 14 and the set of second metal contact pads 18 via a thermo-compression bonding, i.e. by the application of pressure and heat in the absence of an electrical current. In yet another embodiment, the plurality of metal bumps 16 may be bonded to the set of first metal contact pads 14 and the set of second metal contact pads 18 via a thermo-sonic bonding i.e. bonding by using a combination of heat, ultrasonic energy, and pressure generally applied by a bonding tool.

It should be noted herein that the electronic circuit board 10 is applicable for interconnecting the digital electronic component 20 operated at temperatures above 250 degrees Celsius. In accordance with certain embodiments, the digital electronic component 20 may include a wide band gap device such as a silicon carbide device. A plurality of metalized interconnectors 22 may be provided extending from the digital electronic component 20 to the LTCC substrate 12.

The advantage of the LTCC substrate 12 is that the ceramic substrate could be fired below 900 degrees Celsius due to composition of the material. Hence the LTCC substrate 12 permits co-firing with high conductive materials such as silver, copper, gold, or the like. Additionally, the LTCC substrate 12 has low co-efficient of thermal expansion and enhanced flexibility.

As mentioned above the electronic circuit board 10 is applicable for a high temperature device 11 operated at temperature above 250 degrees Celsius. In one embodiment, the high temperature device 11 may be a nitrogen oxide sensor. In another embodiment, the high temperature device 11 may be a drilling device, such as a drilling device for oil and/or gas. In yet another embodiment, the high temperature device 11 may be a digital sensing device. In yet another embodiment, the high temperature device 11 may be an automobile. In a further embodiment, the high temperature device 11 may be a jet engine, or a turbine. It should be noted that the list mentioned herein is not all inclusive and the board may also be applicable for other applications operated above 250 degrees Celsius.

Referring to FIG. 2, an electronic circuit board 10 in accordance with an embodiment is illustrated. As discussed above, the electronic circuit board 10 may include a plurality of metal bumps 16, each metal bump among the plurality of metal bumps 16 may be coupled to a corresponding first metal contact pad among the set of first metal contact pads 14 disposed on the LTCC substrate 12. Similarly, each metal bump among the plurality of metal bumps 16 may be coupled to a corresponding second metal contact pad among the set of second metal contact pads 18 disposed on the digital electronic component 20. In the illustrated embodiment, the board 10 includes a plurality of the LTCC substrates 12 disposed overlapping each other. Although, four LTCC substrates 12 are illustrated, the number may vary depending on the application. A plurality of vias 24 may extend through the plurality of the LTCC substrates 12.

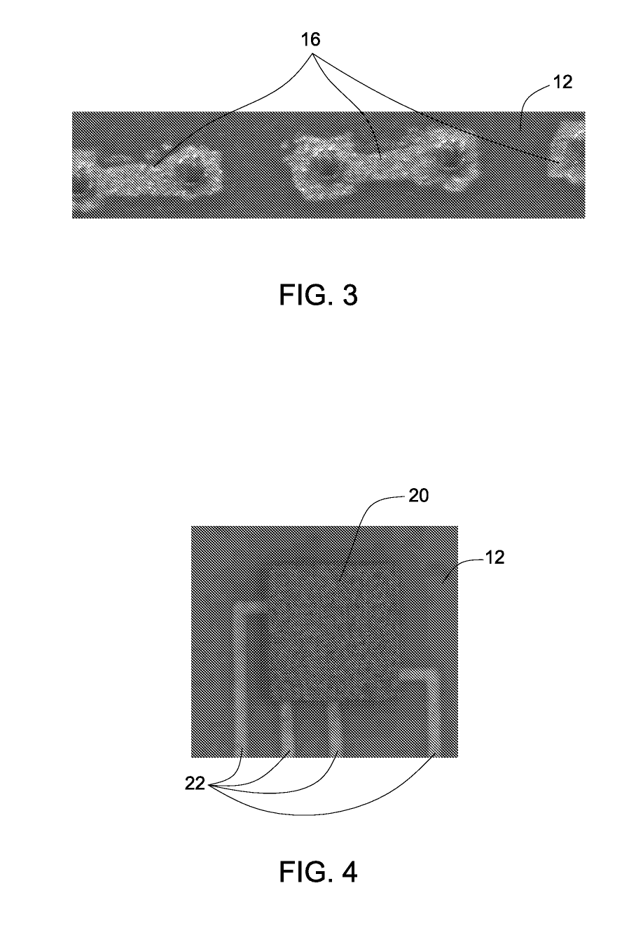

Referring to FIG. 3, a plurality of metal bumps 16 are shown bonded to the LTCC substrate 12 via the set of first metal contact pads 14. In the illustrated embodiment, the metal bumps 16 may include gold stud bumps. Conventionally, an interconnect substrate for high temperature digital electronic device, for example, silicon carbide device is challenged by material limitations due to high temperature. Conventional printed circuit boards for such applications are limited to less than 250 degrees Celsius. Also conventionally, gold wire bonding has been demonstrated for high temperature applications such as digital electronic device, but has issues in a vibration environment due to the softening of the wire due to annealing. In such applications, adjacent wire bonds may also short. Wire bonds also have inductance caused by wire length that limits frequency range and induces parasitic losses.

In the exemplary embodiments discussed herein, the electronic circuit board 10 has enhanced temperature capability, i.e. applicable for digital electronic device 20 operated at temperatures above 250 degrees Celsius. It should be noted herein that digital circuits typically need higher input/output connections than analog circuits. The exemplary electronic circuit board 10 is resistant to the harsh environment (for example, temperature, vibration, corrosion) and provides a low loss (for example, low inductance, low resistance). In accordance with certain embodiments, the LTCC substrate 12 provide a high density circuitry using thick-film printing to 4 mil lines/spaces or using photo-imagable thick-film to 2 mil lines/spaces in single or multilayer circuits.

FIG. 4 shows a diagrammatical representation of a digital electronic component 20 bonded to the LTCC substrate 12. In the illustrated embodiment, the digital electronic component 20 is a silicon carbide device. As discussed in the above embodiments, the plurality of metalized interconnectors 22 is provided extending from the digital electronic component 20 to the LTCC substrate 12. In the illustrated embodiment, the digital electronic component 20 is flip-chip bonded to the LTCC substrate using metal bumps, for example, gold stud bumps.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An apparatus comprising:
a low temperature co-fired ceramic substrate;
a set of first metal contact pads disposed on the low temperature co-fired ceramic substrate; and
a plurality of metalized interconnectors extending between a digital electronic component and the low temperature co-fired ceramic substrate; wherein the apparatus is configured to operate at a temperature greater than 250 degrees Celsius.

2. The apparatus of claim 1, wherein the low temperature co-fired ceramic substrate includes a plurality of low temperature co-fired substrates that are disposed so as to overlap one another.

3. The apparatus of claim 2, further comprising a plurality of vias extending through the plurality of the low temperature co-fired ceramic substrates.

4. The apparatus of claim 1, wherein the set of first metal contact pads comprises at least one of gold, platinum, aluminum, nickel, or copper contact pads.

5. The apparatus of claim 1, further comprising a plurality of metal bumps, each metal bump among the plurality of metal bumps being coupled to a corresponding first metal contact pad among the set of first metal contact pads.

6. The apparatus of claim 5, further comprising a set of second metal contact pads disposed on the digital electronic component, wherein each metal bump among the plurality of metal bumps is coupled to a corresponding second metal contact pad among the set of second metal contact pads.

7. The apparatus of claim 6, wherein the set of second metal contact pads comprises at least one of gold, platinum, aluminum, nickel, or copper contact pads.

8. The apparatus of claim 5, wherein the plurality of metal bumps comprises at least one of gold, platinum, aluminum, nickel, or copper bumps.

9. The apparatus of claim 1, wherein the electronic component comprises a wide bandgap device.

10. The apparatus of claim 1, wherein the apparatus is operatively coupled to a high temperature device operated at a temperature greater than 250 degrees Celsius.

11. The apparatus of claim 10, wherein the high temperature device comprises at least one of a nitrogen oxide sensor, an oil and gas drilling device, a digital sensing device, an automobile, a jet engine, or a turbine.

12. A method, comprising:
providing an apparatus comprising:
a low temperature co-fired ceramic substrate;
a set of first metal contact pads disposed on the low temperature co-fired ceramic substrate;
a plurality of metalized interconnectors extending between a digital electronic component and the low temperature co-fired ceramic substrate; and
utilizing the apparatus at a temperature greater than 250 degrees Celsius.

13. The method of claim 12, comprising providing the apparatus including the low temperature co-fired ceramic substrate having a plurality of low temperature co-fired substrates that are disposed so as to overlap one another.

14. The method of claim 13, comprising providing the apparatus including a plurality of vias extending through the plurality of the low temperature co-fired ceramic substrates.

15. The method of claim 12, comprising providing the apparatus including a set of first metal contact pads comprising at least one of gold, platinum, aluminum, nickel, and copper contact pads.

16. The method of claim 15, comprising providing the apparatus including a plurality of metal bumps comprising at least one of gold, platinum, aluminum, nickel, copper bumps provided in such a way that each metal bump among the plurality of metal bumps is coupled to a corresponding first metal contact pad among the set of first metal contact pads.

17. The method of claim 16, comprising providing the apparatus including a set of second metal contact pads comprising at least one of gold, platinum, aluminum, nickel, copper contact pads disposed on the digital electronic component and each metal bump among the plurality of metal bumps coupled to a corresponding second metal contact pad among the set of second metal contact pads.

18. The method of claim 17, comprising providing the apparatus including each metal bump among the plurality of metal bumps coupled to a corresponding first metal contact pad among the set of first metal contact pads disposed on the low temperature co-fired ceramic substrate and to a corresponding second metal contact pad among the set of second metal contact pads disposed on the digital electronic component via at least one of diffusion bonding, thermo-compression bonding, thermo-sonic bonding.

19. The method of claim 12, comprising providing the apparatus including a set of second metal contact pads disposed on the digital electronic component having a wide bandgap device.
